(19) United States
(12) Patent Application Publication
(10) Pub. No.: US 2008/0158024 A1
(43) Pub. Date: Jul. 3, 2008

(54) Compact user interface for electronic devices

(76) Inventors: Eran Steiner, Kiryat-Ata (IL); Rachel Steiner, Jerusalem (IL)

Correspondence Address: Martin D. Moynihan;PRTSI, Inc., P.O. Box 16446, Arlington, VA, 22215, US

(21) Appl. No.: 12/003,180

(22) Filed: Dec. 20, 2007

Related U.S. Application Data
(60) Provisional application No. 60/876,151, filed on Dec. 21, 2006.

(51) Int. Cl. H03K 17/94; G06F 3/041; G06F 3/033

(52) U.S. Cl. 341/34; 345/173; 345/157

(57) ABSTRACT

An input interface for an electronic device, comprises: a first directionally articulatable central element for pressure operation by a user to indicate one of a first plurality of inputs depending on a direction of application of pressure, and a first directionally articulatable surrounding element arranged at least partially concentrically about the first central element for pressure operation by a user to indicate one of a second plurality of inputs depending on a direction of application of pressure. A four button keyboard constructed from such elements provides a compact but full alphanumeric keyboard, and such elements may double as a cursor manipulation tool. A touchscreen version of the interface is also described, and vectors are used in place of tilting.

### RELATED APPLICATION

This application claims the benefit of priority from U.S. Provisional Patent Application No. 60/876,151 filed Dec. 21, 2006, the contents which are incorporated by reference as if fully set forth herein.

### FIELD AND BACKGROUND OF THE INVENTION

The present invention, in some embodiments thereof, relates to a compact user interface for electronic devices and, more particularly, but not exclusively, to a user interface adapted to be operated principally by the thumb.

User interface devices currently available include the keyboard, the mouse, the remote control, the cellular alphanumeric keyboard, the so-called fast tap keyboard and others. These are now considered in turn.

The Keyboard

The common 87 or 101 button QWERTY keyboards are the main and most efficient user interface for textual input designed for desktops. Desktop models typically have 101 buttons, and laptop versions have typically 87 buttons. To enhance mobility, many new keyboards are cordless or remote, and use RF or IR for the connection to the computing device. For handheld devices the QWERTY keyboard is often too large if the buttons need to be finger operated. In some mobile devices such as handheld assistants and schedulers, where the text input is important, there may be provided a minimized version of the QWERTY keyboard, where the buttons are reduced to the absolute minimum size possible for finger operation. Alternatively a stylus is provided for operation of the buttons. A yet further alternative is to provide a virtual keyboard that displays upon the screen. The virtual buttons can be activated using a stylus pen or similar pointing input device. Another alternative to make the keyboard more compact is that, instead of minimizing the size of the keys, the number of keys may be reduced. The necessary inputs are then achieved by requiring a chord, meaning pressing two buttons together to provide a different input. An example of a chord-based keyboard is the so-called “frogpad” shown in FIG. 1.

Mouse

The mouse is the most common and some would say the most efficient pointing or cursor manipulation device for the desktop computer. In the laptop or mobile computer it is often replaced by the compact touchpad or a tiny joystick, and in some cases by a trackball or a mouse-pen. In smaller devices where a pointing/choosing input device is required there is a small tilt button that allows movement in 4 directions. The button is very compact, and suits the human thumb but is less efficient and less accurate than the others.

The Remote Controller

Originally invented to complement the television set, the remote controller was invented in order to change channels and control the volume without the viewer having to leave his seat. Nowadays more functions are required to be controlled remotely since in addition to the television there are many Multimedia accessories such as the audio system, video, DVD, cable/satellite converters and the like. Eventually the computer is expected to become the multimedia and communication center for the house. Nowadays, numerous computer peripherals are available as remote or cordless devices. The mouse was the first one to go remote and to be unleashed from the computer's cord and is able to assist with remote control of multimedia. The common keyboards soon followed and furthermore were enhanced with addition of multimedia buttons to control the volume, play, stop and the like. Keyboards are conventionally connected to the computer by wire but today many of them are wireless/cordless, using RF (Radio frequency), IR (Infra Red) or BT (Blue Tooth) technologies to transmit the signals. A few new Multimedia keyboards also include a remote controller built-in with an IR transmitter.

The universal remote control is a remote control device that is intended to work with a range of devices, and has evolved parallel to the cordless keyboard. The universal remote control uses standard IR signals and company-specific signals. In recent models, a mouse tilt button has been added to some of the devices in order to apply an additional remote pointing device to control a computer. In some highly advanced universal remote controllers a full QWERTY keyboard is available upon opening as per the example in FIG. 2. FIG. 2 shows a prior art remote controller having a closed state with standard multimedia buttons—left hand side. At the right hand side the cover is shown opened to reveal the full alphanumeric keyboard.

### The Game Console

Computer games often work with game consoles, to allow the user to interact with the game. The game consoles usually include buttons for different functions and one, or more typically two, joysticks for controlling the movement of objects in the game. Games consoles are not generally however designed for transmitting text, a disadvantage since many games today include text messaging facilities.

The Cellular Alphanumeric Interface

The mobile phone is now very widespread, and many applications are built thereon such as a camera, scheduler etc. Many of those applications require an interface for inserting text, for example text messaging using SMS, answering E-Mail messages and the like and even making entries in the address book. Internet addresses as well as or instead of telephone numbers may also be required in address books as voice over Internet protocol (VoIP) calling becomes more common. There is no room on a cellular telephone to insert individual keys for a full alphabet and therefore the numeric keys are assigned with the alphabet on top of the numerals. That is to say each key is assigned with several letters, and the number of taps on the key is used to distinguish between the numbers and the different letters. Alternatives tried out include adding a text pad additional to the numeric pad. In some mobiles, the keypad area had to be enlarged to be able to insert the required alphabet and so the overall size of the mobile was increased, making this a less than practical solution. Exemplary so-called “fastap” mobile phone keypads, which integrate text input into numerical keys through the use of multiple presses are shown in FIG. 3.

A basic problem is that the full alphanumeric keyboard designed for finger operation is too large for mobile devices. The best interface for text input is indeed the common QWERTY keyboard but due to the above their use is limited to those devices that are larger anyway such as the desktop or laptop. Pocket sized devices simply cannot accommodate either the size or weight of a full QWERTY keyboard. The cordless keyboard is more mobile but still does not fit in a pocket. Beyond this the cordless keyboard only gives free mobility for a few meters around the computer it is operating with.

Attempts to shrink the common QWERTY keyboard down to the size of a mobile, handheld device require that the size of the keys and the distance between them is minimized. Children's fingers may be able to use such small keyboards but it is harder for bigger fingers to carefully aim and press only the chosen button. Thus typing on such a keyboard is rather slow compared to standard size keyboards and blind or touch typing is particularly difficult.

As mentioned above, the game console is made for only one purpose which is playing the game. However network games in particular may require the sending of text for short messages and chats between the players. Game consoles that are connected to personal computers use the computer's keyboard to send text messages and the two kinds of input are not merged.

The mouse or other pointing device is currently a separate device from the keyboard. The pointing device, whether a mouse or a stylus or any other pointing device, is in the current art separate from the keyboard even though the two are never simultaneously used. The space required for the pointing device could be reduced if the mouse could be an integral part of the keyboard.

In consideration of all the above issues it is desirable to provide:

a handy and easy to use keyboard that can be put inside the pocket;

keyboards that are small in size and yet, with buttons that are not too small for effective operation by even the fattest of fingers;

keyboards with an easy to remember character layout, such as an alphabetical order or similar so it will be still possible to type the right keys without the need to look at/for them;

keyboards suitable for holding in one hand. It is even more desirable to allow typing using the same hand that is doing the holding, say using the thumb;

a keyboard with an integrated pointing device such as a mouse integrated within the keyboard;

game consoles that are able to send text for chats and advanced functions during a game.

Documents of relevance include the following patents or patent applications, GB2381854, JP2004038829, US2002149566, WO02073588, and US2002110237, the contents of which are hereby incorporated by reference herein.

### SUMMARY OF THE INVENTION

The present embodiments relate to a keyboard constructed from a limited number of keys or buttons, articulated to tilt in varying directions to give different inputs. Some of the buttons of the keyboard include a central articulated element surrounded by a peripheral element separately articulated from the central element.

According to a first aspect of the present invention there is provided an input interface for an electronic device, comprising:

a first directionally articulatable central element for pressure operation by a user to indicate one of a first plurality of directions of application of pressure, and

a first directionally articulatable surrounding element arranged at least partially concentrically about the first central element for pressure operation by a user to indicate one of a second plurality directions of application of pressure.

In an embodiment, an input character is assigned to at least some of the directions of each plurality of directions such that application of pressure in a respective direction allows for input of the assigned input character to the electronic device.

In an embodiment, the first and second directionally articulatable elements are virtual elements of a touch screen, the interface comprising vectorized detection ability to detect directionality of application of pressure.

An embodiment may comprise a second directionally articulatable central element for pressure operation by a user to indicate one of a third plurality of directions of application of pressure, and

a second directionally articulatable surrounding element arranged at least partially concentrically about the first central element for pressure operation by a user to indicate one of a fourth plurality of directions of application of pressure.

An embodiment may comprise a third directionally articulatable central element for pressure operation by a user to indicate one of a fifth plurality of directions of application of pressure.

An embodiment may comprise a fourth directionally articulatable central element for pressure operation by a user to indicate one of a sixth plurality of directions of application of pressure.

In an embodiment, an input character is assigned to at least some of the directions of each plurality of directions such that application of pressure in a respective direction allows for input of the assigned input character to the electronic device.

In an embodiment, the first directionally articulatable central element is resiliently mounted on a rounded base through which a plurality of contacts are activatable about the base depending on the direction.

In an embodiment, the plurality of contacts comprises four contacts and the first plurality of inputs comprises nine inputs.

In an embodiment, the resilient mounting comprises an elastic surface through which conductive connections pass to the contacts.

In an embodiment, the first surrounding element is located on the elastic surface over a plurality of contact elements.

In an embodiment, the first surrounding element is located over four contact elements and the second plurality of inputs comprises eight inputs.

An embodiment may comprise a soft decision making utility for discriminating between the directions based on patterns of contact caused by the direction of application of pressure.

In an embodiment, the soft decision making utility comprises learning functionality to learn patterns of contact of individual users.

In an embodiment, the first directionally articulatable central element is operable as a cursor manipulation tool.

In an embodiment:

the first directionally articulatable central element for pressure operation by a user is to indicate one of a plurality of directions for manipulation of an on-screen cursor depending on the direction of application of pressure, and

the first directionally articulatable surrounding element is arranged for pressure operation by a user to indicate an on-screen manipulation according to a direction of application of pressure.

In an embodiment, the on-screen manipulation is page scrolling in a first mode and cursor manipulation in a second mode.

In an embodiment, the central element further comprises a non-directional manipulation operable as a mouse click.

According to a second aspect of the present invention there is provided an input interface for an electronic device, comprising:

at least one input element configured both for inputting characters and for manipulation of an on-screen cursor.

In an embodiment, the input element is directionally articulated such that directional pressure is differentiable into a plurality of different input characters and into different directional manipulations for the on-screen cursor.

In an embodiment, the input element is a central input element having at least nine differentiable inputs.

An embodiment may comprise a surrounding element having at least eight differentiable inputs.

An embodiment may be integrated as part of a mobile telephone as a mobile telephone interface.

According to a third aspect of the present invention there is provided an input interface comprising:

a series of input symbols arranged around a central point, a vectorized detector for pressure input as vectors having at least a direction, and

a selector for selecting one symbol of the series based on a currently detected vector.

In an embodiment, the symbols are soft symbols of a touch screen.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volitile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified diagram illustrating a prior art compact keypad using the chord-key concept;

FIG. 2 is a diagram of a prior art remote-control-type device showing how opening of a cover reveals a complete keyboard;

FIG. 3 is a simplified diagram showing prior art mobile telephone keyboards in which alphabetic input is integrated into a numerical keyboard via multiple tap-type operations;

FIG. 4 is a simplified diagram illustrating two-element separately articulated multi-input keys according to a first preferred embodiment of the present invention;

FIG. 5 is a telephone keypad constructed using one- and two-element articulated multi-input keys according to a preferred embodiment of the present invention;

FIG. 6 is an exploded diagram illustrating the construction of a central element of an input key according to an embodiment of the present invention;

FIGS. 7A, 7B and 7C are schematic diagrams illustrating how four contacts are able to discriminate nine different inputs according to a preferred embodiment of the present invention;

FIG. 8 is a variation of the keypad of FIG. 5 specifically intended to mimic a game consol;

FIGS. 9A and 9B illustrate a variation of the keypad of FIGS. 5 and 8 to provide dialing to a simple telephone;

FIG. 10 illustrates an alternative construction of a tilt button to accommodate both central and surrounding or frame members, according to a further embodiment of the present invention;

FIG. 11 illustrates the layers of FIG. 10 in greater detail;

FIG. 12A illustrates a conventional soft keyboard;

FIG. 12B illustrates a prior proposal for a soft keyboard dedicated for thumb use;

FIG. 13 is a simplified diagram that illustrates a soft keyboard according to another embodiment of the present invention;

FIG. 14 is a comparative diagram illustrating a memo application for a mobile computing device, firstly using a conventional soft keyboard and secondly using the soft keyboard of FIG. 13;

FIG. 15 is a simplified flow chart illustrating how thumb movements on the surface of a touch screen may be translated into precise selection of symbols according to an embodiment of the present invention;

FIG. 16 is a continuation of the flow chart of FIG. 15 to deal with the case of a surrounding frame; and

FIG. 17 is a diagram indicating different vectored presses and their results.

### DESCRIPTION OF EMBODIMENTS OF THE INVENTION

The present invention, in some embodiments thereof, relates to a compact user interface for electronic devices and, more particularly, but not exclusively, to a user interface adapted to be operated principally by the thumb.

The present embodiments comprise a keyboard constructed from articulated keys or buttons. Certain of the keys are double keys which include separately articulated central and surrounding elements. The remainder of the keys may be single keys comprising only a single element. The central elements provide nine distinct input positions, and the surrounding elements provide eight distinct input positions, so that one double key can provide seventeen different inputs. Two double keys and two single keys are thus sufficient to provide the entire alphanumeric keyboard together with punctuation and basic symbols.

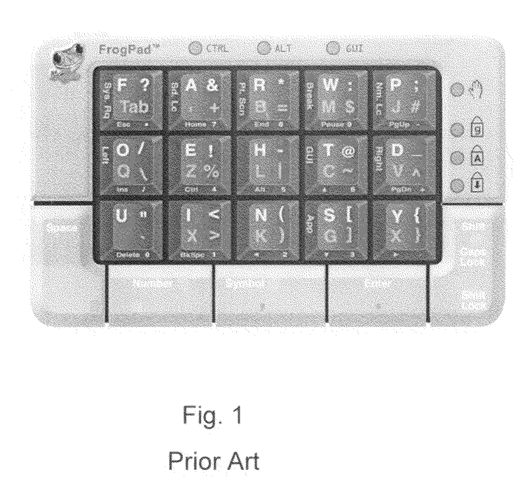

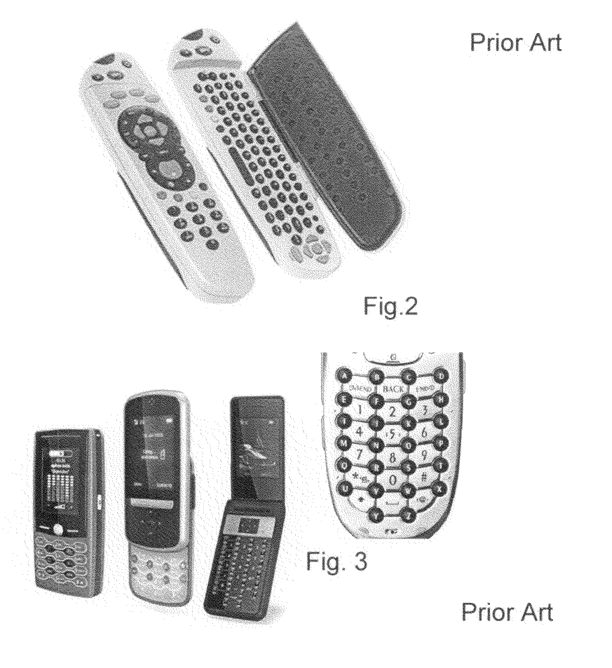

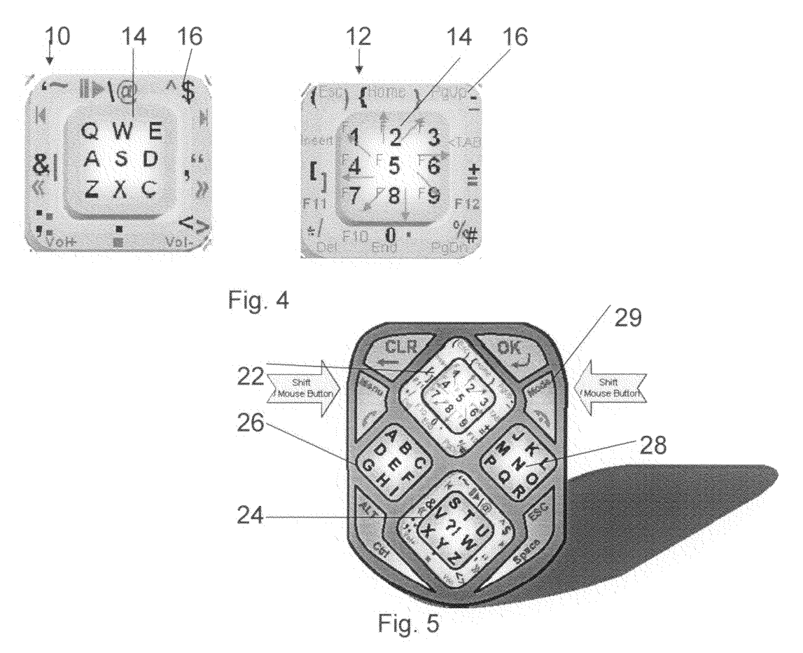

For purposes of better understanding some embodiments of the present invention, as illustrated in FIG. 4 onwards of the drawings, reference has already been made to conventional (i.e., prior art) keyboards of various kinds, as illustrated in FIGS. 1-3.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Referring now to the drawings, FIGS. 1 to 3 have been discussed above in the background. FIG. 4 illustrates buttons 10 and 12, for application to a compact input interface for an electronic device. Each button includes a central element 14 which can be pressed by a user to indicate one of the marked inputs depending on the direction of application of the pressure. The central element 14 has a central input surrounded by eight peripheral inputs. The separate directions that are recognized for the button are a central press to indicate the central input, a press to each side, and a press to each diagonal, as illustrated by arrows on button 12. As will be explained below the central element is articulated to allow it to tilt. In a preferred embodiment the element is sized and shaped for convenient operation by a user's thumb.

The central element 14 may be surrounded by a surrounding element 16. The surrounding element is partly or wholly concentric about the central element 14 and likewise allows pressure operation by a user to select between different inputs at different locations about the periphery of the element based on a detected direction of application of pressure. The surrounding element 16, which may form a frame about the central element, may likewise be shaped for operation by the thumb.

The central element and the surrounding element may be separately articulated so as to be independently tiltable. As will be explained below, the central element has nine separately distinguishable input positions and the peripheral element has eight such positions.

Reference is now made to FIG. 5, which shows a full alphanumeric keyboard 20 comprising four buttons, two two-part buttons 22 and 24 made of central and peripheral elements, and two one-part buttons 26 and 28, made of central elements alone. The particular keyboard layout is designed for a mobile telephone. Any combination of one part and two-part buttons may be used so as to provide the appropriate number of inputs for the appropriate compactness of the overall keyboard. As shown in FIG. 5, six different multiple input elements are provided in a pattern of four buttons, complemented simple buttons around the outside which cover mode changes, very common functions and telephone specific functions.

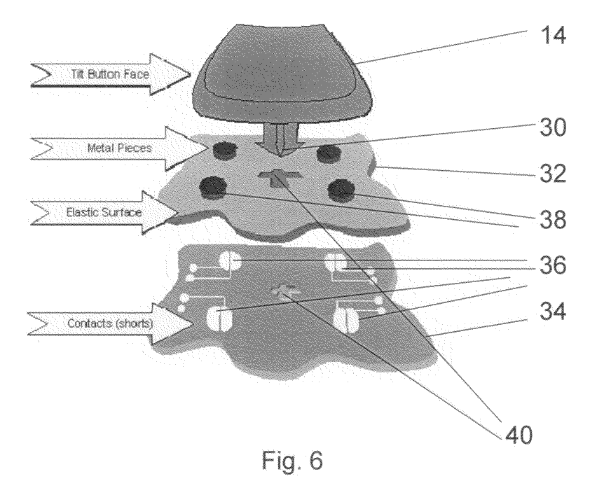

Reference is now made to FIG. 6, which is a simplified exploded diagram illustrating possible construction details of a button element such as central element 14 according to one preferred embodiment of the present invention. Central element 14 includes a rounded base 30. Rounded base 30 sits on an elastic sheet 32 which provides the arrangement with resilience, and separates the element 14 from an operational surface 34 which includes contacts or shorts 36. The contacts correspond with the corners of the element 14. Metal pieces 38 in the elastic sheet 32 correspond to the contacts and are pressed against their respective contacts when the element 14 is tilted towards them.

Likewise the surrounding element 16 is located on the elastic sheet 32 and may have the same arrangement of contacts coinciding with the corners.

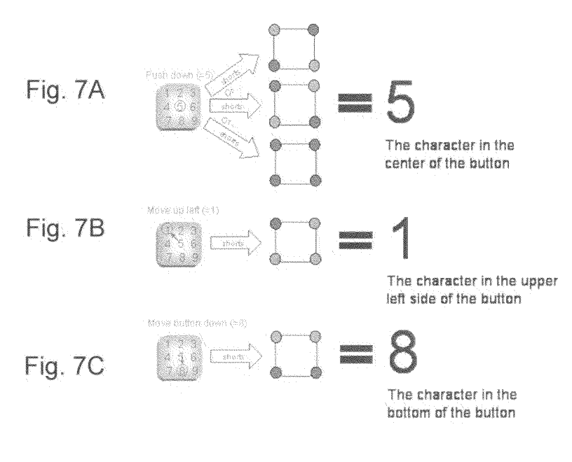

Reference is now made to FIGS. 7A-7C, which illustrate how pressure on just four different contacts can allow for the element to carry up to nine different inputs. The inputs may be categorized into central inputs such as the ‘5’ in FIG. 7A, peripheral corner inputs, such as ‘1’ in FIG. 7B and peripheral edge inputs, such as the 8 in FIG. 7C. As shown in FIG. 7A, central pressure is indicated by pressures being indicated at all contacts or at any rate evenly across different sides. Thus pressure at all four contacts indicates the central element, but so does pressure at pairs of diagonals, both being non-directional combinations.

As shown in FIG. 7B, a peripheral corner element is indicated by pressure at the corresponding contact. Thus detection at the upper left hand side contact indicates the ‘1’ input.

FIG. 7C illustrates how pressure at two adjacent contacts indicates selection of the corresponding peripheral edge element. Thus detection at the two lower contacts indicates the selection of the ‘8’ input.

The surrounding element likewise has corner contacts and up to eight peripheral inputs may be distinguished, in the same way as above. Clearly in the case of the surrounding element there is no centrally located input.

In one embodiment, a soft decision making utility is provided to discriminate between the different inputs based on patterns of contact caused by the direction of application of pressure. The soft decision utility may distinguish between durations of contact and the like and may also include a learning facility to learn the idiosyncrasies of individual users.

As mentioned above, the keyboard of the present embodiments, as shown in FIG. 5, consists of four main buttons, two double and two single.

Each button has tilt movement ability to enable it to tilt in all directions and may also be pushed directly downwards. The tilt ability provides four main directions which are up, down, left & right. Combining those directions with diagonals gives us another four directions that sum to eight different directions. Adding a push direction or directly down provides nine distinguishable actions that can be achieved with a single tilt element.

Two of the four keys include a surrounding element of the kind discussed. The surrounding element holds additional functions and, as discussed above, applies another eight different actions due to its own tilt ability.

Thus a keyboard of the kind shown in FIG. 5, with two double keys and two single keys, has four central elements with nine different inputs each, making 36 actions. Another two surrounding elements that surround two of the four central element, give another 16 actions, giving the keyboard a total of 52 different actions. This is still short of the 101 keys of the common QWERTY keyboard. However use of chord keys and mode selection may allow multiple uses of certain of the input positions as needed. For example navigation arrows may be assigned to the numeric pad. Pressing of a mode key may toggle between the arrow keys and the numerals, as is well-known in the art, or combination presses may be used to achieve certain results. A mode change button 29 is provided on the keyboard of FIG. 5 for this purpose, and allows each of the input positions to have two meanings. Another 29 available keys are however all that is required to provide nearly all the utility that the standard QWERTY keyboard.

It is noted that through use of the navigation keys, the central element 16 can double as a cursor manipulation tool, moving an on-screen cursor across the screen. Thus a keyboard input function and a cursor manipulation function are united on the same element.

There are a number of ways available to the person skilled in the art to implement the tilt button. The implementation shown in FIGS. 6 and 7 is merely exemplary. The tilt button may also double as a navigation button and thus replace the need for a mouse.

As explained above with reference to FIG. 6, a tilt button central element may be constructed by assembling a button with a round base, to enable smooth tilting. The base is pressed into an elastic surface, for example rubber or elastomer. As explained, the elastic surface may contain metal pieces at its four opposite corners around the button's location to produce the short circuits that may be translated into signals. As an alternative to metal pieces, piezoelectric crystals may be used. The crystals deform under pressure to produce an electric current that may be detected. The amount of pressure may vary, thus changing the amount of current. Thus instead of on-off type detection there is analog detection, which may give more information to a soft detection application of the kind discussed above.

Tilting the button in a given direction, say towards the upper corner in FIG. 5, presses down the corresponding metal piece located in the pressed corner. This in turn creates an electric short at the underlying contact that may be translated into a digital signal to be processed. Tilting the button diagonally may press two metallic pieces located in the direction of the tilt at the two corresponding corners. These create two electrical shorts, which are be translated to the input assigned at the particular diagonal location, as explained above in respect of FIG. 7. When a button is pressed down directly downwards, all four metal pieces, or perhaps just two of the metal pieces but located in opposite corners indicate a non-direction press and invoke the input located in the middle of the tilt button.

Referring now to board 34 in FIG. 6, an indentation may be provided in the electronic board that allows the button to descend when pressed directly down so that all the metallic pieces touch and create electric shorts. However for any other angle the button does not enter the indentation and only the contacts in the selected direction are activated. That is to say, at any other angle, the base misses the indentation and thus only reaches the desired contacts. It is not possible to both tilt the button and push it down. Thus directional and non-directional pressure may be clearly distinguished. The button's rounded base may also be barred to prevent it from twisting.

As explained, two of the four main buttons are double buttons which include a surrounding element. The surrounding elements are preferably constructed in exactly the same way as the central elements except that they lack a central base and there is no meaning to them being pushed directly downwards. The surrounding element adds another eight inputs.

As explained, the tilt buttons are intended to fit the human thumb, so a preferred size is a square of side approximately 1-1.5 Cm. The surrounding buttons then fit the main button size, thus a square of side around 2.5-3 Cm with a 1-1.5 Cm side cut out in the center would be appropriate.

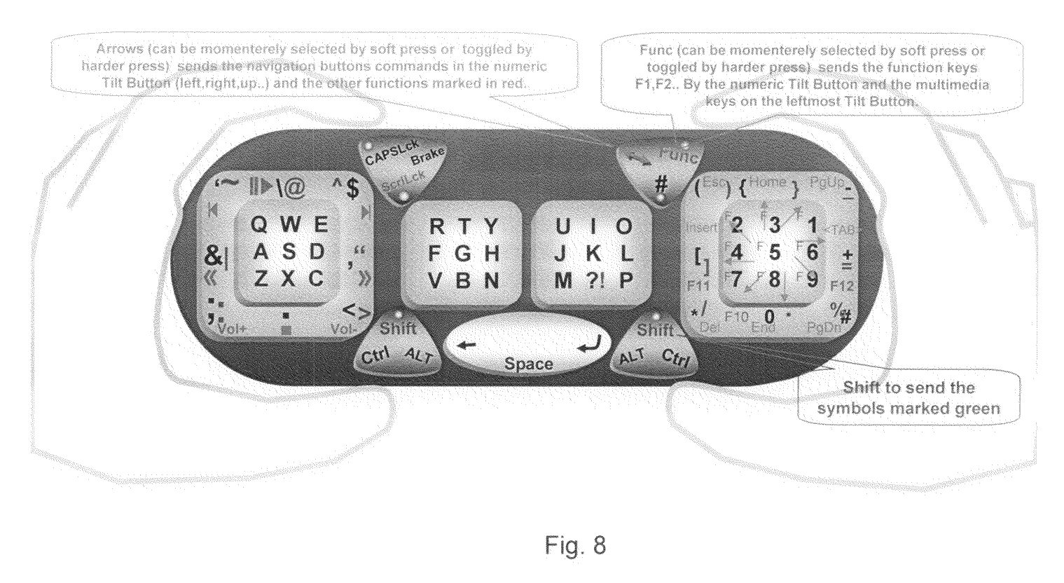

FIG. 8 is an alternative layout to FIG. 5 of a keyboard including two double buttons and two single buttons. Common to both FIGS. 5 and 8, there are four main central elements that between them cover the main inputs such as numeric keys and alphabet. The surrounding buttons are assigned punctuation and symbols, such as comma, ( ) { };: . . . . In the numeric tilt button, 22 in FIG. 5, the surrounding button is assigned the 0, * and # signs. Other inputs may be distributed around the buttons to easily allow common actions like Enter, Space, ESC, Clear/Delete and the multifunctional keys such as the ALT key, Ctrl and Shift. The FIG. 8 layout doubles as a games console, providing control of a game in that the outermost central elements double as joysticks, and at the same time allowing full alphanumeric input. The FIG. 5 layout provides cellular telephone functionality and at the same time full alphanumeric functionality and mouse functionality.

Different Modes for Key Assignments

As explained above, in order to enable more inputs than the 52 available key positions, while preserving the compact and easy to remember, 4 button format, additional modes may be available. In each mode, the tilt buttons have different to outputs. Mode and Function buttons may be provided to switch between modes, as shown in FIGS. 5 and 8.

In the standard mode the numeric tilt button 22 produces numerals and the other tilt buttons 24, 26 and 28 produce the letters of the alphabet of the main assigned language.

A single shift may transfer between upper and lower case letters, or a CAPS lock key may be used for this purpose. Shift plus CAPS lock may produce a double shift back to the original as per the standard keyboard. The button surrounding the main tilt button may include more characters, that complete the possible set of inputs available.

An arrow and Second Language mode is provided as follows:

The numeric tilt button outputs the up, down, left & right arrows and the combinations in diagonal directions. The button surrounding the numeric element may produce such special functions as TAB, Home, End, INS Del, PgUp . . . .

The Alphabet tilt buttons may produce a second language letters set or certain extra characters that may be required in some languages.

A special function mode may be defined in which the numeric keys may produce Function keys output such as F1, F2 . . . F12. The button surrounding the main alphabet tilt button may be able to send some multimedia functions such as Vol. + or −, Stop; Play/Pause, Next, Rev., Fwd. . . .

A mouse mode may be defined in which the numeric tilt button is used as a mouse to navigate as a pointing device through menus or similar. The surrounding element of the numeric tilt button may be used in this mode for scrolling. At the user's selection the surrounding element may alternatively be used as a coarse or faster mouse, leaving the delicate mouse movements to the numeric mouse button in the middle. The mouse click may be, according to user preferences, provided by pushing the center of the numeric tilt key or by using one of the shift buttons on the side.

A universal remote controller mode may be defined for typical multimedia functions needed by remote control operated devices. Many multimedia devices are remotely controlled by IR signals. An IR interface, (LED) may be installed with the keyboard so that the keyboard can function as a remote controller. In this mode, the inputs are assigned functions of known remote controllers, to send signals via the IR interface that are recognized by the multimedia devices to change volume, channels etc. As with known universal controllers, it is able to learn a function from the dedicated IR so as to repeat and act alike. A compact keyboard of the kind described herein may provide all of the functions generally required of the remote controller plus a full range of alphanumeric signals.

Individual keyboards are preferably designed as most appropriate for their designated uses. Three different designs of tilt buttoned keyboards are described in this document as follows. First of all there is the compact diamond keyboard as shown in FIG. 5. The compact diamond design is suitable for mobile devices such as cellular phones, remote control etc. FIG. 8 shows a game console design, in which two outer double keys serve also as joysticks. The console design is also suitable for handheld computer devices, for which it would be placed at the bottom of the screen.

The handheld computer device thus has not only a keyboard but also a built in game console.

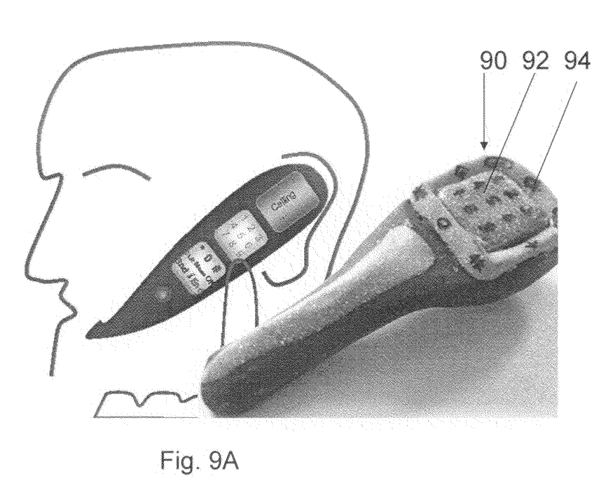

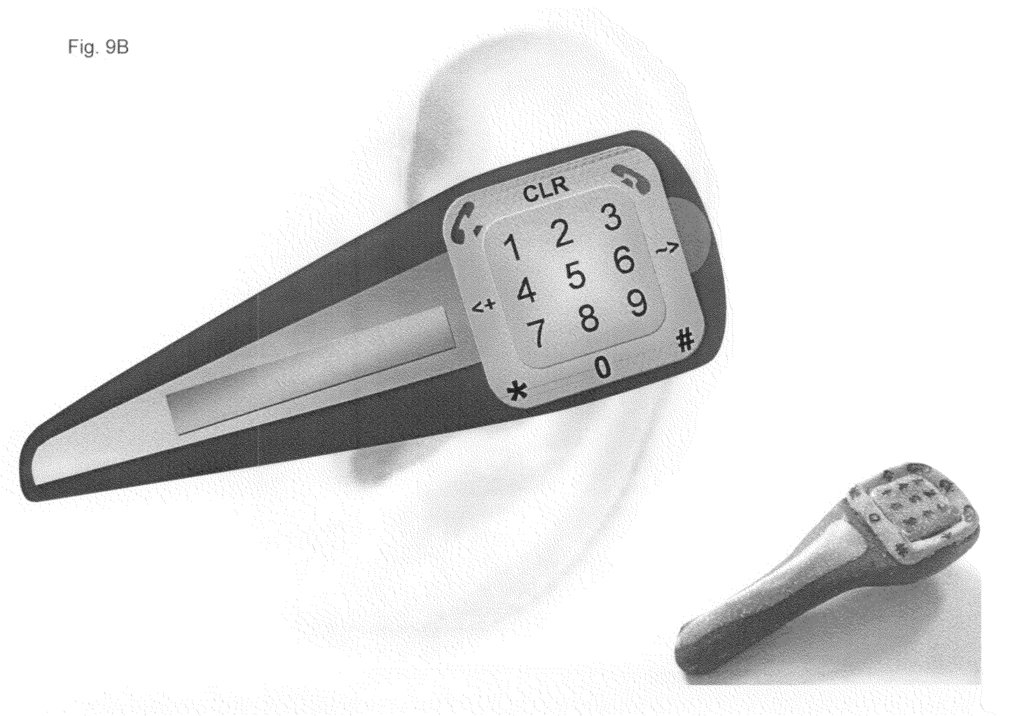

FIGS. 9A and 9B illustrate the user of directional elements in a hands free dial button. In FIG. 9, the dial of a telephone minimized into one double tilt button 90 which includes central element 92 and surrounding element 94. Such an arrangement allows dialing from the hands free or any handset without the need to look for or miss the numbers. There is only a single button to press.

Returning now to FIG. 6, the shape of the tilt button face for the central element is preferably flattened with a slight sunken area in the middle so the finger may find its way easily to the center of the element. However the flatter the face the more compact it becomes, so for the most miniature devices it is possible to make the button substantially flat with elevated edges. The edges help the fingers find the button and apply the pressure required for the tilting action in the various directions.

The design for the surrounding elements may also be flattened with elevated edges to assist with the tilt action. The surrounding elements are preferably also somewhat elevated from the central element to enable easy passage between the central and surrounding elements without striking the edges of the central element.

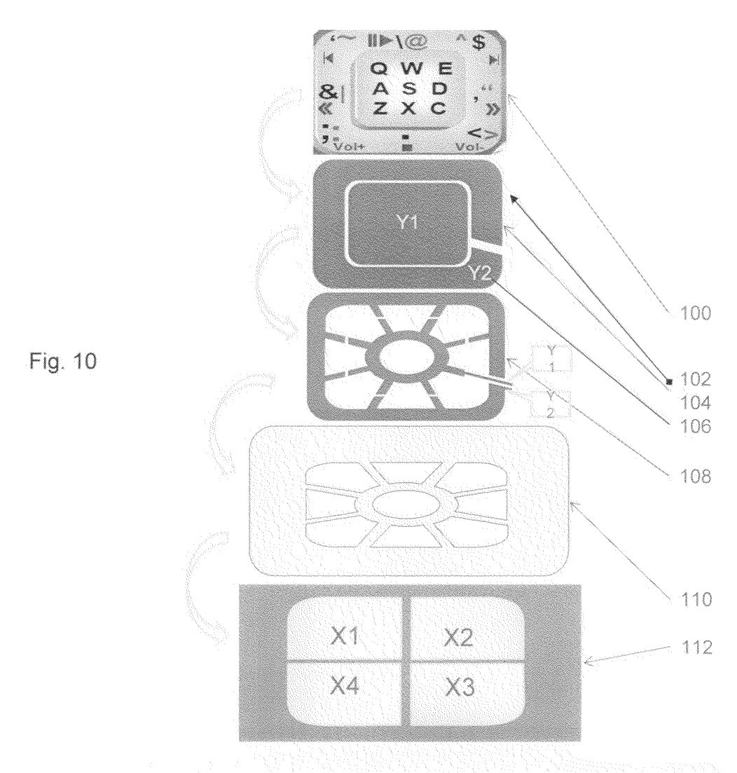

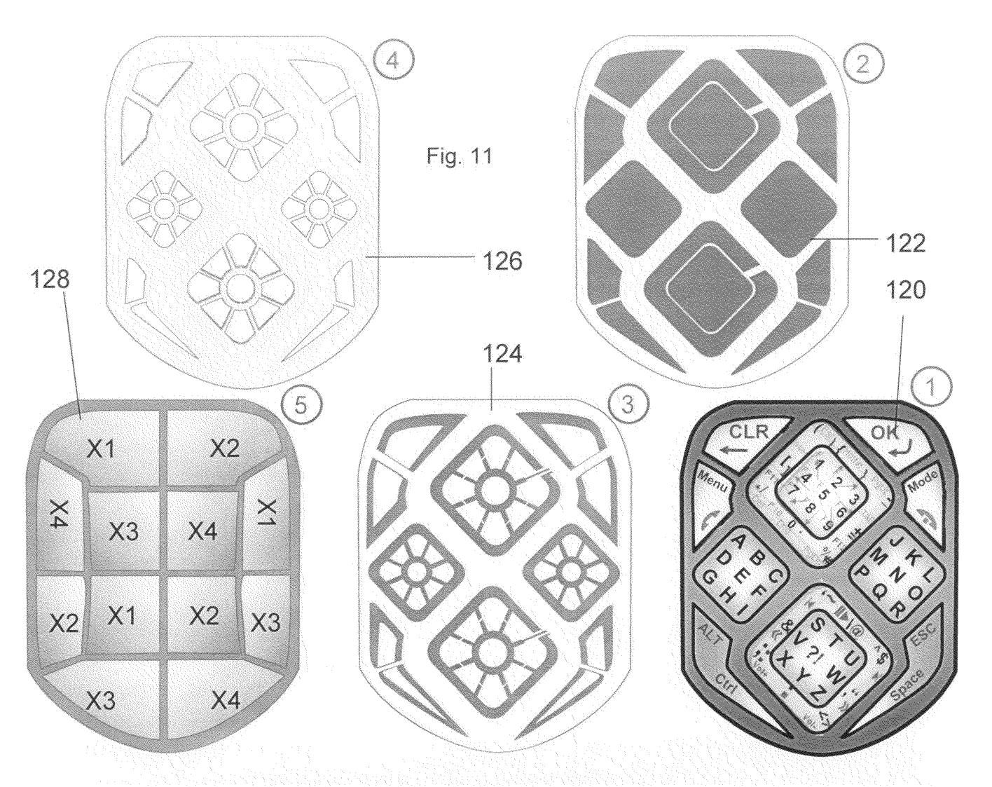

Reference is now made to FIG. 10, which illustrates an alternative assembly for a tilt button. A printed layer 100 is used to cover the button. A flat conductor surface 102 consists of inner part Y1-104 and outer part Y2-106. The flat conductor surface allows for separate connection to one of two Y inputs of a processor depending on whether the other or inner part of the tilt button has been pressed, and connects to X inputs depending on the orientation of the press via the underlying surface 108. The flat conductor surface may additionally have a rounded surface on top for comfortable finger or thumb interaction. Underlying surface 108 comprises a thin conductor such as aluminium foil, which actually connects to the Y1 and Y2 inputs of a processor. A thin plastic or elastomer isolator 110 sits under the conductive surface to separate the unpressed button from the orientation detectors X1 . . . X4 in PCB layer 112.

TABLE 1
Input-symbol relationship for button construction of FIG. 10

| X4 | X3 | X2 | X1 | Y2 | Y1 |
|---|---|---|---|---|---|
| 0 | 0 | 0 | 0 | NULL- | NULL- |
| 0 | 0 | 0 | 1 | ‘ | Q |
| 0 | 0 | 1 | 0 | $ | E |
| 0 | 0 | 1 | 1 | \ | W |
| 0 | 1 | 0 | 0 | < | C |
| 0/1 | 1 | 0/1 | 1 | NULL | S |
| 0 | 1 | 1 | 0 | , | D |
| 1 | 0 | 0 | 0 | ; | Z |
| 1 | 0 | 0 | 1 | & | A |
| 1 | 0/1 | 1 | 0/1 | NULL | S |
| 1 | 1 | 0 | 0 | . | X |

Thus the button shown in FIG. 10 is able to obtain two types of information, X information regarding orientation of a press, and Y information regarding whether an inner or an outer part of the button has been pressed. Table 1 below indicates how different symbols are identified from the information.

Reference is now made to FIG. 11, which is a simplified diagram showing examples for the different layers for a complete keyboard for a cellular device.

Printed key layout cover 120 provides the visible layer for the user to press and see the symbols.

Layer 122 comprises conductor button plates which correspond to layer 102 in the previous figure. The layer may have shaped plastic on top and pressing of the layer establishes connections to the various processor inputs. Layer 124 comprises conductor foils for connecting to processor inputs. Layer 126 is the elastomer isolator layer, a resilient layer to ensure that there is no connection when the button is not being pressed. Layer 128 has printed PCB output conductors.

Smart touch-screen virtual keyboards and two-way screens and technology are known, for example as the technology that enables an Iphone™ and host device to wirelessly operate as one.

One recently published patent application covers a new method for activating virtual keys of a touch-screen virtual keyboard.

The virtual keyboard learns which keys are touched more often than others and adjusts the sensitivity of each key accordingly. Certain keys are given more weight than others, depending on the likelihood of the person pressing one key over another. That likelihood is determined by the person's distance of touch from the closest key, as well as frequency of use.

A touch pad, as opposed to a visual keyboard, can give visual feedback and the keys can change according to circumstances. Generally a touch screen uses transparent conductive materials to activate coordinate sensing so that the location of a fingertouch can be identified.

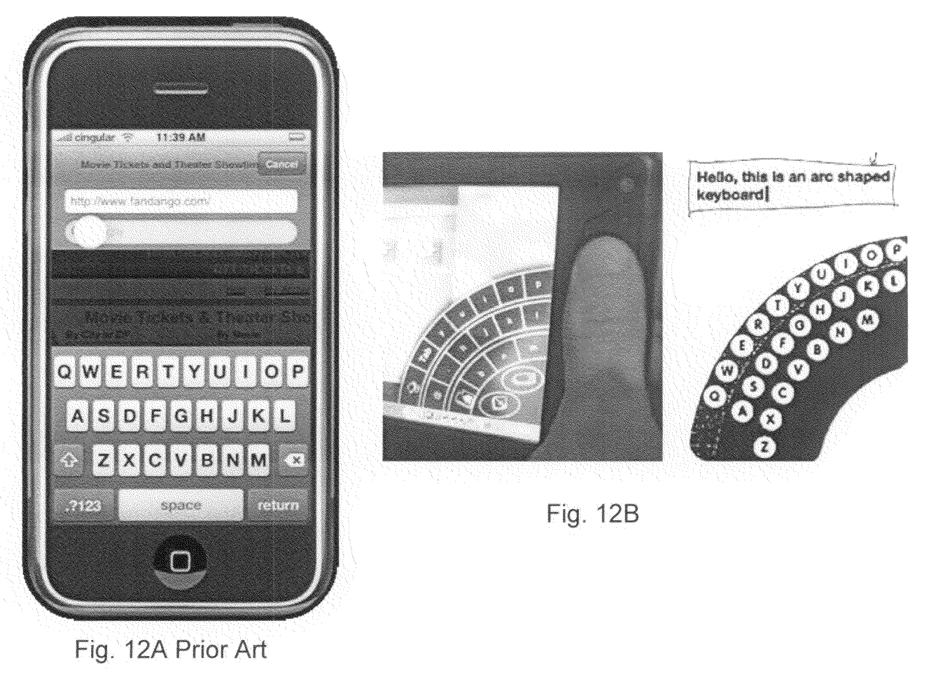

FIG. 12A indicates a standard keyboard layout provided as a touch screen. As noted the screen takes up space and is not especially adapted for thumbs.

FIG. 12B indicates a prior proposal for a touch screen that is configured for use of a thumb. An arc shaped keyboard contains all the necessary keys in a radius of movement appropriate for a thumb. Nevertheless the screen still takes up a great deal of space on the keyboard.

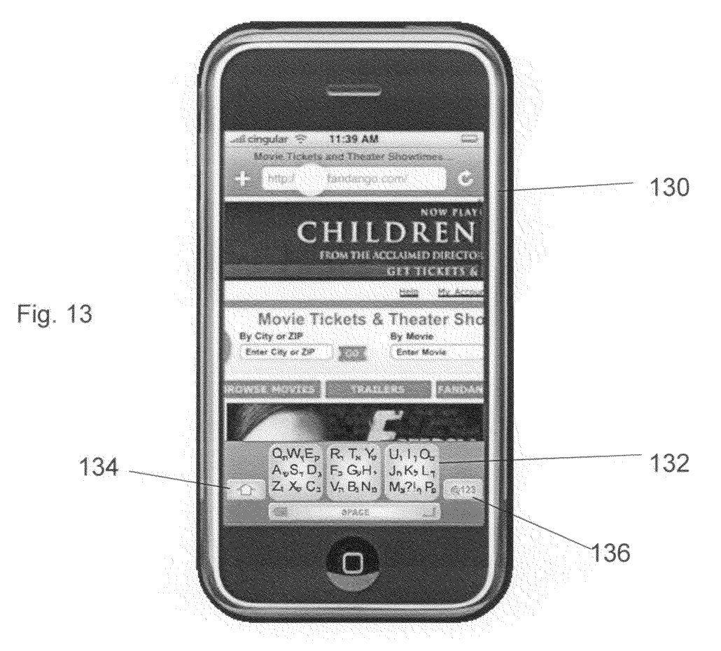

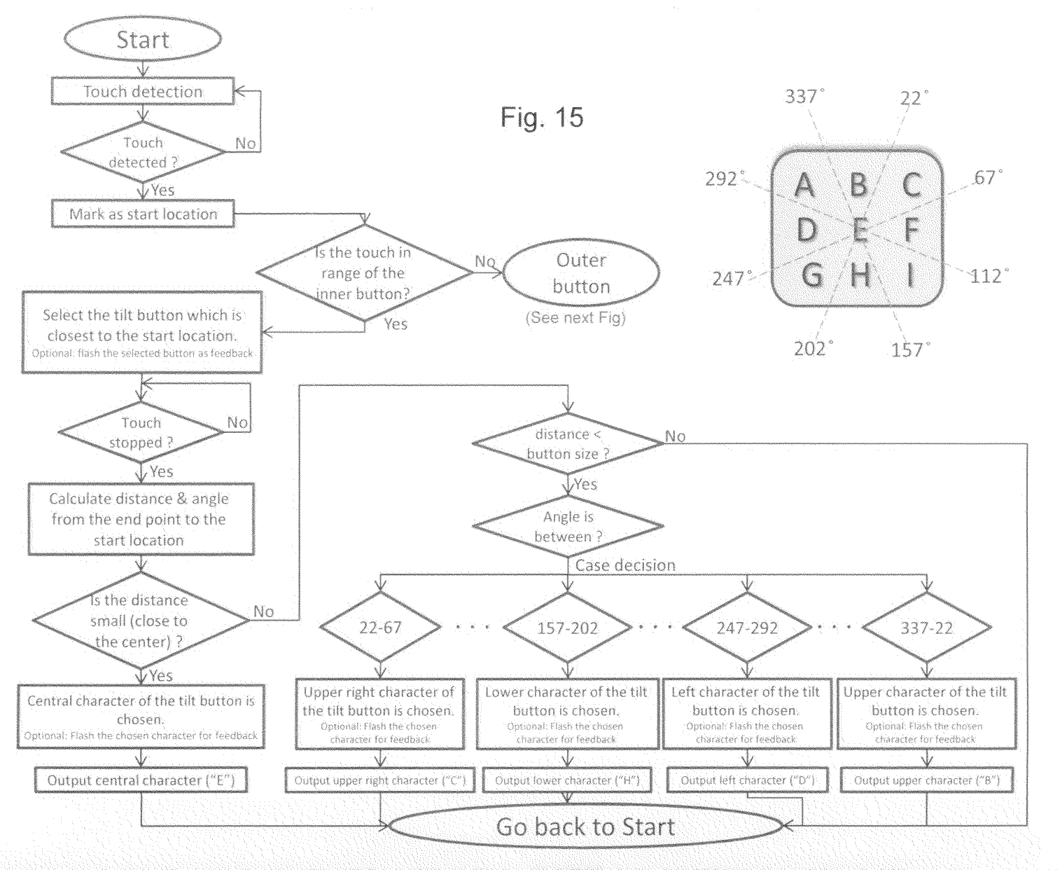

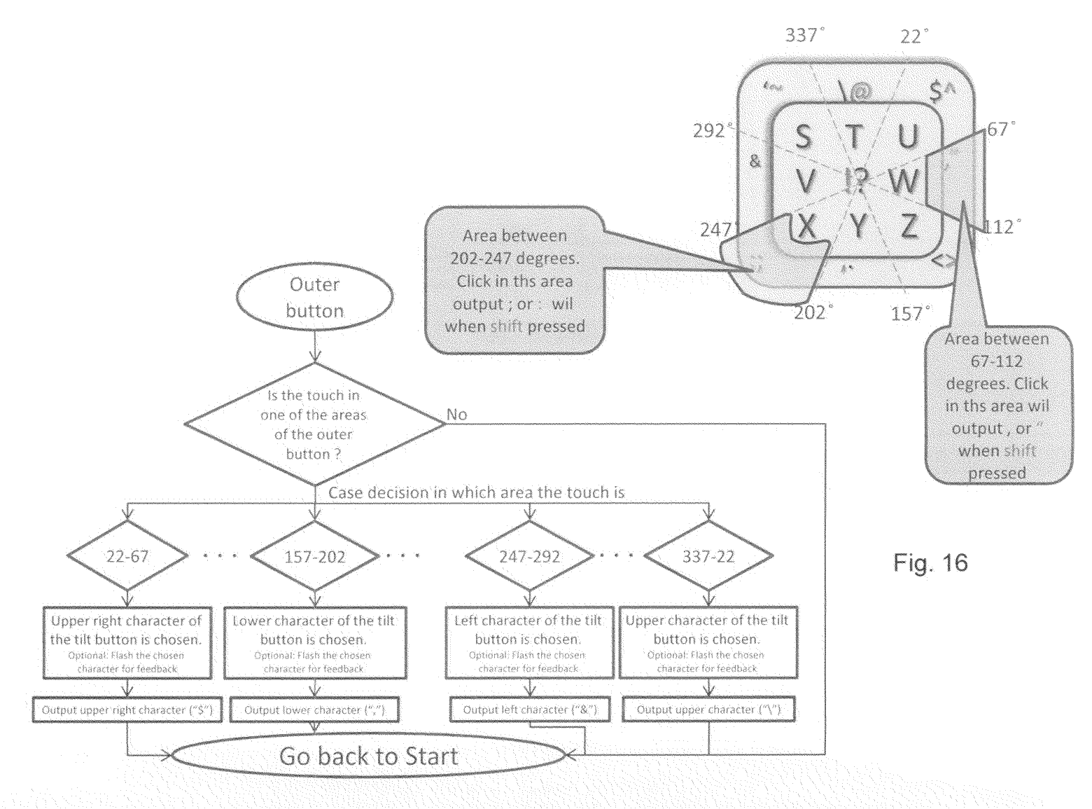

Reference is now made to FIG. 13, in which a touch-screen according to an embodiment of the present invention is incorporated into a portable digital device 130. The keyboard consists of soft versions of the buttons discussed above. It will be appreciated that in a soft screen it is not actually feasible to tilt the buttons. Nevertheless the motions that would have led to tilting can be utilized by using the touch screen coordinate detection system to detect vectors of motion of the thumb as it moves over the button. Thus, although an individual button is too small for accurate pressing, a motion in a direction represented by that button can nevertheless be recognized. Thus touching the leftmost button with a stroke moving from the center upwards and leftwards may be recognized as the letter Q, etc. A press on the shift key 134 or number key 136 causes the symbols to change on the buttons, so that no additional space is required. In the version illustrated surrounding frames are not used due to the possibility of ambiguous vector results, although this may be offered as an option for those users who would find it useful. FIGS. 15 and 16 below in fact give full flows to cover the case of a surrounding frame.

The vector preferably detected in terms of a start point and a direction. Alternatively a direction and an end point may be detected as appropriate.

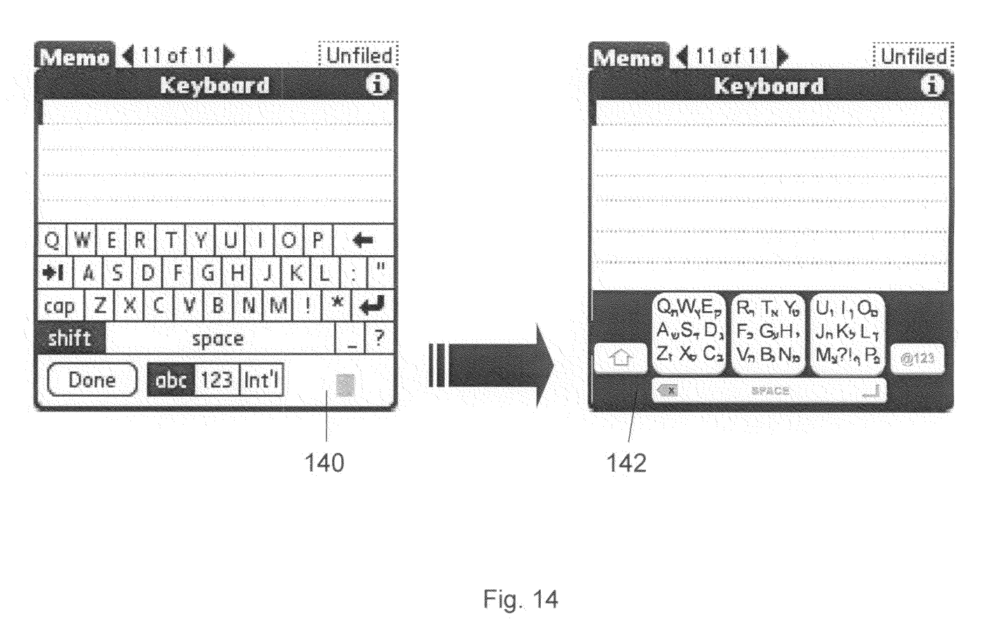

Reference is now briefly made to FIG. 14 which is a comparison between two touchscreen-based memo applications 140 and 142. Application 140 uses a conventional screen and as can be seen, does not give much room for the application itself, despite the fact that each key is also fairly compact, requiring skill to use. Application 142 uses the present embodiment and rapid typing with a thumb is possible, at the same time leaving plenty of room on the screen for the application itself. No stylus is required and the device can be held in the palm of the same hand as the thumb that is doing the typing, leaving the other hand free.

Reference is now made to FIG. 15, which is a simplified flow diagram illustrating a logical procedure for recognizing which symbol has been selected.

Initially, a touch is detected and the starting location is noted. The tilt button closest to the start location is selected if in range. If there is an outer button (surrounding frame) and the initial touch is outside the range of the inner button, then the nearest surrounding frame is selected. The procedure for the outer frame is given in FIG. 16 below.

In the case of inner button selection, the touch is followed to an end point. Once the touch stops then the distance and angle from the start point is calculated. If the distance is small, and the touch was close to the center then the symbol corresponding to the central character is selected. For longer distances outer buttons are selected according to the angles measured.

Referring now to FIG. 16, which is a simplified flow chart illustrating the procedure with the outer frames. If the initial touch is outside the region of the inner button then it is assumed that the outer frame is intended. In this case the symbols are far enough apart that touches are unambiguous and thus all that is needed is to calculate an angle from the center in order to select a symbol.

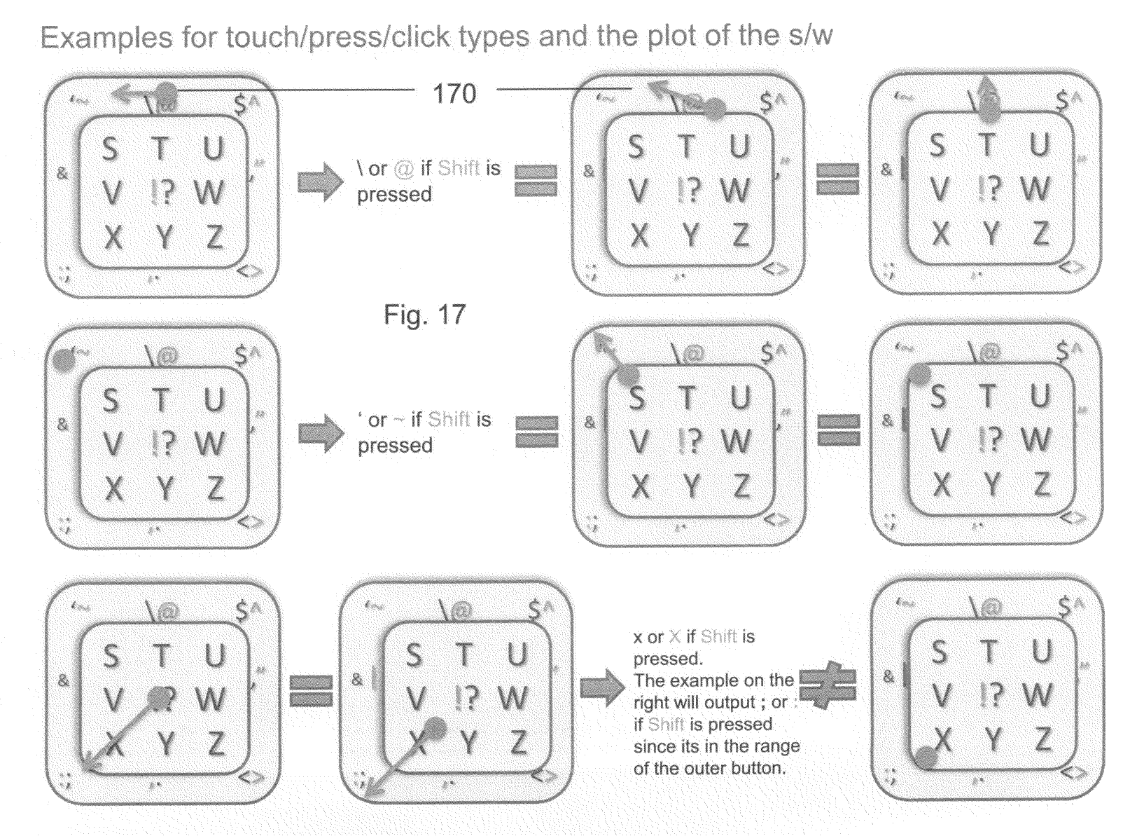

The flexibility of the system is illustrated by FIG. 17. In FIG. 17 arrows 170 indicate the different vectored presses, with the round base indicating the start point and the arrowhead indicating the direction. In each row all of the different vectored presses give rise to the same symbol. In the first two rows the outer frame is indicated and in the third row the symbol x at the bottom left hand corner of the inner button is indicated.

The skilled person will appreciate that there are many possible ways to connect between the compact interface and the controlled devices. The interface may be integrated into the device if the device is compact or by wire or wireless according to the application it is designated to service.

Control by wire using a keyboard cable interface and a mouse interface may be the most simple connection technologically but may lose much of the mobility advantages that the compact keyboard provides. The Universal Serial Bus (USB) is a common way to connect but again is limited to a very short range.

An IR remote connection may use any short range wireless technology, for example Infra Red as in remote controllers. The IR interface may allow the interface to act as a universal remote controller as described above. For connecting to a computer, the computer requires an IR receptor which is easy to install in most computers through the serial or USB port. As an alternative, an RF cordless connection may be used using technologies such as short range RF including Blue-Tooth (BT). Connecting to a computer would require a BT receiver at the computer, but this is common with up-to-date computers and easy to implement.

Game consoles generally prefer wire connections such as USB, because it has much less delay than the wireless connection. Game consoles are sensitive to delay, which may affect game response time.

Within the mobile devices the keyboard would generally be integrated into the device. Even so it may have an IR port to control remote devices such as TV and Multimedia. A tilt button numeric dial application for hands free phone operation may likewise be integrated into the device. An integrated keyboard may also be suitable for mini game consoles with built-in screen.

Integrated keyboards are powered by their host devices. In wired connections such as through USB or serial, the computer device may be the power source. In wireless remote controller applications, a battery may provide the power for the translating circuit that converts the electrical shorts from the keyboard to data and for the transmitting circuit that sends the data as signals.

The compact keyboard provides a small number of buttons simply designed using the movement of the button in a smart way to produce many functions. The compactness and the possibility to use materials that are commonly used in today's technology, may lower the cost in comparison to complicated interfaces.

The tilt button as such, but not the double key, already exists and it has already become the common navigation button in mobile devices. Implementation of the keyboard is thus simplified, as is its integration into applications.

The small number of buttons that create a whole keyboard allows the fingers to quickly learn for blind-typing. The idea of placing two eight-position tilt elements around two other nine-position central elements decreases the total number of buttons seen by the eyes and gives a cleaner line that is easier to remember, since human memory is associative.

Since the layout is easy to remember, it should not take long for users to get used to the new layout and learn the keyboard.

Children who have grown up into the technological world quickly discover and interact with all the innovations. Many accessories and game consoles require abilities with thumbs. Children of today are very skilled and use their thumbs remarkably fast in games, remote control and for typing SMS messages. The present embodiments take this into account.

The present embodiments make a compact keyboard that can be held in the palm of one's hand or may be slipped easily into a pocket. Its being handy will make it a closer and more personal companion and increase the range of possible applications. One possibility is to have a stand-alone personal keyboard that the user keeps for attaching to all of his devices. In any event the present keyboard is suitable for even the smallest of devices, in that it can be added to these devices without increasing the device footprint.

A main application of the present embodiments would be in the keyboard of a cellular phone or any mobile handheld assistant, where a major design constraint is to keep the device pocked sized. However, many other applications can be integrated with such a keyboard and can be selected easily by pressing a selector switch.

A list of possible applications is the following:

i. A compact & wireless PC keyboard.

ii. A wireless pointing device—or tilt button mouse.

iii. Universal IR remote controller for all multimedia and TV devices.

iv. Cordless game console.

v. VoIP phone and dialer for the PC (By adding an audio transmitter).

vi. Speaker for mutes (By adding a speaker to read the input via text to speech, or even simply to read out the individual letters)

The term “comprising” means “including, but not limited to”. This term encompasses the terms “consisting of” and “consisting essentially of”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. An input interface for an electronic device, comprising:
a first directionally articulatable central element for pressure operation by a user to indicate one of a first plurality of directions of application of pressure, and
a first directionally articulatable surrounding element arranged at least partially concentrically about said first central element for pressure operation by a user to indicate one of a second plurality directions of application of pressure.

2. The input element of claim 1, wherein an input character is assigned to at least some of said directions of each plurality of directions such that application of pressure in a respective direction allows for input of said assigned input character to said electronic device.

3. The input element of claim 1, wherein said first and second directionally articulatable elements are virtual elements of a touch screen, said interface comprising vectorized detection ability to detect directionality of application of pressure.

4. The input interface of claim 1, comprising a second directionally articulatable central element for pressure operation by a user to indicate one of a third plurality of directions of application of pressure, and
a second directionally articulatable surrounding element arranged at least partially concentrically about said first central element for pressure operation by a user to indicate one of a fourth plurality of directions of application of pressure.

5. The input interface of claim 4, further comprising a third directionally articulatable central element for pressure operation by a user to indicate one of a fifth plurality of directions of application of pressure.

6. The input interface of claim 5, further comprising a fourth directionally articulatable central element for pressure operation by a user to indicate one of a sixth plurality of directions of application of pressure.

7. The input interface of claim 6, wherein an input character is assigned to at least some of said directions of each plurality of directions such that application of pressure in a respective direction allows for input of said assigned input character to said electronic device.

8. The input interface of claim 1, wherein said first directionally articulatable central element is resiliently mounted on a rounded base through which a plurality of contacts are activatable about said base depending on said direction.

9. The input interface of claim 8, wherein said plurality of contacts comprises four contacts and said first plurality of inputs comprises nine inputs.

10. The input interface of claim 9, wherein said resilient mounting comprises an elastic surface through which conductive connections pass to said contacts.

11. The input interface of claim 9, wherein said first surrounding element is located on said elastic surface over a plurality of contact elements.

12. The input interface of claim 11, wherein said first surrounding element is located over four contact elements and said second plurality of inputs comprises eight inputs.

13. The input interface of claim 1, further comprising a soft decision making utility for discriminating between said directions based on patterns of contact caused by said direction of application of pressure.

14. The input interface of claim 13, wherein said soft decision making utility comprises learning functionality to learn patterns of contact of individual users.

15. The input interface of claim 1, wherein said first directionally articulatable central element is operable as a cursor manipulation tool.

16. The input interface of claim 1, wherein:
said first directionally articulatable central element for pressure operation by a user is to indicate one of a plurality of directions for manipulation of an on-screen cursor depending on said direction of application of pressure, and
said first directionally articulatable surrounding element is arranged for pressure operation by a user to indicate an on-screen manipulation according to a direction of application of pressure.

17. The input interface of claim 16, wherein said on-screen manipulation is page scrolling in a first mode and cursor manipulation in a second mode.

18. A cursor manipulation device according to claim 16, wherein said central element further comprises a non-directional manipulation operable as a mouse click.

19. An input interface for an electronic device, comprising:
at least one input element configured both for inputting characters and for manipulation of an on-screen cursor.

20. The input interface of claim 19, wherein said input element is directionally articulated such that directional pressure is differentiable into a plurality of different input characters and into different directional manipulations for said on-screen cursor.

21. The input interface of claim 18, wherein said input element is a central input element having at least nine differentiable inputs.

22. The input interface of claim 21, further comprising a surrounding element having at least eight differentiable inputs.

23. The input interface of claim 21, integrated with a mobile telephone as a mobile telephone interface.

24. An input interface comprising:
a series of input symbols arranged around a central point,
a vectorised detector for pressure input as vectors having at least a direction, and
a selector for selecting one symbol of said series based on a currently detected vector.

25. The input interface of claim 24, wherein said symbols are soft symbols of a touch screen.
